(19) United States
(12) Patent Application Publication
(10) Pub. No.: US 2025/0317332 A1
(43) Pub. Date: Oct. 9, 2025

(54) DYNAMIC GAIN CONTROL FOR CLOCK AND DATA RECOVERY COMPONENTS

(71) Applicant: Lumentum Operations LLC, San Jose, CA (US)

(72) Inventors: Gianluca FALANGA, San Jose, CA (US); Jingcheng ZHANG, Saratoga, CA (US); Ricardo SAAD, Plano, TX (US)

(21) Appl. No.: 18/971,960

(22) Filed: Dec. 6, 2024

Related U.S. Application Data
(60) Provisional application No. 63/557,211, filed on Feb. 23, 2024.

(51) Int. Cl. H04L 25/03; G01K 7/42

(52) U.S. Cl. CPC H04L 25/03019; G01K 7/425

(57) ABSTRACT

In some implementations, a clock and data recovery (CDR) chip includes a continuous time linear equalizer (CTLE) circuit and a temperature measurement component, wherein the CTLE circuit is configurable with a variable gain value, and wherein the variable gain value is based on an output of the temperature measurement component.

### CROSS-REFERENCE TO RELATED APPLICATION

This patent application claims priority to U.S. Provisional Patent Application No. 63/557,211, filed on Feb. 23, 2024, and entitled “DYNAMIC TRANSCEIVER OPTIMIZATION FOR STRESS RECEIVER SENSITIVITY.” The disclosure of the prior application is considered part of and is incorporated by reference into this patent application.

### TECHNICAL FIELD

The present disclosure relates generally to electronic devices and to dynamic gain control for a clock and data recovery chip.

### BACKGROUND

Clock and data recovery is a process by which a receiver recovers timing information from an incoming signal, where there is no accompanying clock signal, and by which the receiver re-times received data using the timing information. For example, when data is transmitted or retrieved without a timing reference, and when a receiver is to process the data synchronously with transmission of the data, an electronic device may perform clock and data recovery to determining timing information for synchronous processing of the received data. An optical transceiver may include a clock and data recovery (CDR) chip that performs the clock and data recovery process. Some CDR chips may include continuous time linear equalization (CTLE) circuits to improve signal performance at a receiver. For example, a CTLE circuit may modify a signal (e.g., by amplifying higher frequencies within the signal) to attempt to bring different frequency components of the signal to a similar amplitude, which may improve receiver performance.

### SUMMARY

In some implementations, a CDR chip includes a CTLE circuit; and a temperature measurement component, wherein the CTLE circuit is configurable with a variable gain value, wherein the variable gain value is based on an output of the temperature measurement component.

In some implementations, a method includes receiving, by a controller, information identifying a temperature measurement of a CDR chip; determining, by the controller, a control signal based on the temperature measurement; and providing, by the controller, the control signal to configure a gain value of a CTLE circuit of the CDR chip.

In some implementations, an optical transceiver includes a temperature measurement component; and a CDR chip, wherein the CDR chip, and the CDR chip including: a CTLE circuit, wherein the CTLE circuit is set with a variable gain value, wherein the variable gain value is set based on a temperature measurement performed by the temperature measurement component.

### BRIEF DESCRIPTION OF THE DRAWINGS

FIG. 1 is a diagram of an example implementation associated with dynamic gain control for CDR components.

FIGS. 2A-2G are diagrams of an example associated with dynamic gain control for CDR components.

FIG. 3 is a flowchart of an example process associated with dynamic gain control for CDR components.

### DETAILED DESCRIPTION

The following detailed description of example implementations refers to the accompanying drawings. The same reference numbers in different drawings may identify the same or similar elements.

A CDR chip within an electronic device, such as an optical transceiver, may include a CTLE circuit. The CTLE circuit may be configured to equalize a low-pass response of a lane (e.g., a channel) to compensate for high-frequency losses in the lane. By equalizing the low-pass response of the lane, the CTLE circuit improves a quality of the received signal, thereby reducing a likelihood of errors in reception and decoding, or improving frequency tuning accuracy, among other examples. The CTLE circuit may have a discrete quantity of frequency responses that are set as discrete and static values within a register of the CDR chip. In other words, the CTLE circuit may apply a static gain value that is configured in the CDR chip.

A stressed receiver sensitivity (SRS) represents a minimum optical power in an optical modulation amplitude (OMA) that is used to achieve a configured bit error rate (BER) (e.g., a predetermined or set BER value) with a degraded receiver input. SRS measurements may be performed with an optical path, between a transmitter and receiver, that is associated with a 0 picosecond (ps) per nanometer (nm) (ps/nm) dispersion. Additional details regarding SRS measurements are described with regard to the Institute of Electrical and Electronics Engineers (IEEE) standard 802.3. An electronic device, such as an optical transceiver, may be configured to satisfy a specification in accordance with a standardized requirement or a particular use case. The electronic device may be exposed to varying temperatures, such as temperatures in a range from −40 degrees Celsius (° C.) to 85° C. The OMA level at a specific BER value may be based on a CTLE gain that is applied to a lane.

However, a static value for a CTLE gain may result in the OMA level at a specific BER value not satisfying a specification at some temperatures. For example, at relatively high temperatures within the operating temperature range and at relatively low CTLE gain values, the OMA level at a specific BER value may not satisfy the specification. Accordingly, setting a static, low CTLE gain value may result in performance not satisfying one or more performance requirements. A higher gain value may be set as a static gain value to ensure that the OMA level at a specific BER value satisfies the threshold across the operating temperature range. However, at relatively low temperatures within the operating temperature range, and with the CTLE gain set to a relatively high value, the CDR may have a loss of lock (LOL) scenario in some chromatic dispersion conditions. A loss of lock scenario may result in traffic not being passed through an electronic device, which may interrupt traffic through an optical system. Accordingly, setting a static, high CTLE gain value may result in performance not satisfying one or more performance requirements.

Some implementations described herein may enable dynamic optical transceiver control for SRS. For example, a CDR chip may include a CTLE circuit and a temperature measurement component. The CDR chip may use a temperature measurement, such as a temperature measurement of the CDR chip, a temperature measurement of a printed circuit board assembly (PCBA), a temperature measurement of a transceiver, or another temperature measurement associated with the CTLE circuit, performed using the temperature measurement component, to dynamically control a CTLE gain of the CTLE circuit. In this case, by dynamically controlling the CTLE gain, the CDR chip enables satisfaction of an OMA level at a specific BER value without a loss of lock scenario occurring. For example, the CDR chip may satisfy the OMA level at the specific BER value threshold (without loss of lock) across a configured temperature range of −40° C. to 85° C. using a range of CTLE gains from approximately −1 decibels (dB) to approximately 3 dB. In this way, the CDR chip may enable high performance optical communications in optical transceivers without loss of lock and without excess BER.

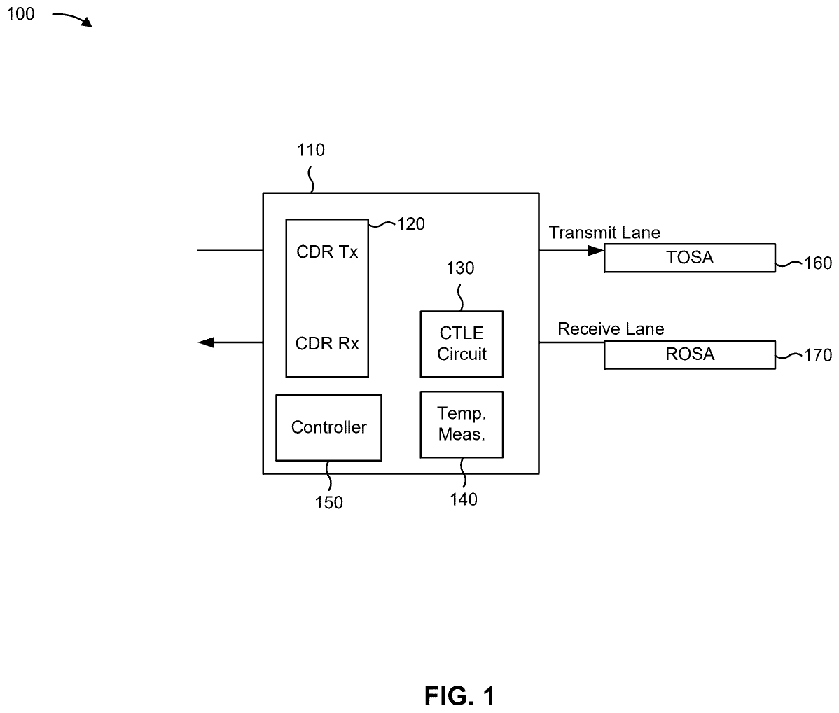

FIG. 1 is a diagram of an example electronic device 100 used within an optical transceiver and associated with dynamic gain control of a CTLE circuit. As shown in FIG. 1, the electronic device 100 includes a CDR chip 110, which includes a CDR transmit and receive component 120, a CTLE circuit 130, a temperature measurement component 140, a controller 150, a transmit optical sub-assembly (TOSA) 160, and a receiver optical sub-assembly (ROSA) 170. In some implementations, the electronic device 100 may include one or more other components coupled to the CDR chip 110 or a component thereof. For example, the CDR chip 110 may include a Mach-Zehnder (MZ) transmitter driver associated with modulating a signal from the CDR transmit and receive component 120. In some implementations, the electronic device 100 may include a CDR transmit module or a CDR receive module.

Additionally, or alternatively, the CDR chip 110 may receive an input signal from a first physical interface (e.g., a TP1 interface) in a transmit lane and provide an output signal to a second physical interface (e.g., a TP2 interface) and to the TOSA 160 in the transmit lane. Additionally, or alternatively, the CDR chip 110 may receive an input signal from a ROSA 170 and a third physical interface (e.g., a TP3 interface) in a receive lane and provide an output signal to a fourth physical interface (e.g., a TP4 interface) in the receive lane. Although some physical interfaces are described herein, other physical interfaces or architectures may be used.

In some implementations, the CTLE circuit 130 may be disposed in a receive lane of the electronic device 100. For example, the CTLE circuit 130 may equalize a low-pass response of a received signal in the receive lane of the electronic device 100. In this case, the CTLE circuit 130 may equalize the low-pass response by applying a gain to the received signal. In some implementations, the CTLE circuit 130 may provide a variable gain to the received signal. For example, the CTLE circuit 130 may apply a first gain at a first operating temperature of the electronic device 100 (or the CDR chip 110) and a second gain at a second operating temperature of the electronic device 100. In some implementations, the CTLE circuit 130 may provide the variable gain based on at least in part on receiving a control signal from the controller 150. For example, the controller 150 may receive information identifying a temperature measurement performed by the temperature measurement component 140 and may generate a control signal as a response to the temperature measurement. In some implementations, the temperature measurement may be performed on the CDR chip 110, a housing of the CDR chip 110, the electronic device 100, a housing of the electronic device 100, or another component. In this case, the control signal may be associated with selecting a CTLE gain setting that results in an OMA level at a specific BER value (e.g., under stress receiver sensitivity conditions) of the receive lane satisfying a configured specification without a loss of lock occurring. In some implementations, the temperature measurement component 140 may include a thermistor integrated into the CDR chip 110. Additionally, or alternatively, another temperature component of the CDR chip 110 (or of the electronic device 100) may report a temperature to the controller 150. For example, a thermistor on a PCBA, which includes or is connected to the CDR chip 110, may report a temperature to the controller 150. Additionally, or alternatively, a temperature measurement may be derived from another measurement performed by a component associated with the CDR chip 110.

In some implementations, the controller 150 may store information identifying a mapping of temperature values to gain values. For example, the controller 150 may store a lookup table identifying a gain value to configure for the CTLE circuit based on receiving an indicator of a particular temperature measurement. Additionally, or alternatively, the controller 150 may implement logic for selecting the gain value. For example, the controller 150 may implement interpolation logic for performing an interpolation on a set of discrete gain values based on a received temperature value. In other words, when the controller 150 receives information identifying a temperature value that is between two discrete temperature values of a lookup table, the controller 150 may identify two corresponding gain values for the two discrete temperature values and may interpolate between the two corresponding gain values to identify an interpolated gain value that corresponds to the received temperature value. In this case, the controller 150 may perform linear interpolation, logarithmic interpolation, machine learning based interpolation, artificial intelligence based interpolation, or another interpolation procedure to determine the two corresponding gain values.

Additionally, or alternatively, the controller 150 may perform an extrapolation process. For example, when the controller 150 receives information identifying a temperature value that is outside a configured range of temperature values in a lookup table, the controller 150 may extrapolate, using the discrete temperature values and the corresponding configured range of gain values in the lookup table, to determine a gain value for the identified temperature value. Additionally, or alternatively, the controller 150 may perform a predictive process. For example, when the controller 150 receives information identifying a set of different temperature values over a period of time, the controller 150 may predict a temperature value at a next time interval and proactively predict and implement a gain value for the next time interval. Additionally, or alternatively, the controller 150 may use a control loop process. For example, the controller 150 may determine a first gain value from a temperature, set the first gain value, and receive feedback identifying an OMA level at a specific BER value resulting from the first gain value. In this case, if the OMA level at a specific BER value does not satisfy a specification, the controller 150 may set a second gain value and implement the second gain value. The controller 150 may continue setting gain values until the specification is satisfied for the temperature.

In some implementations, the controller 150 may use a set of factors to determine a gain value (or may be configured with a lookup table that is based on a set of factors). For example, the controller 150 may (e.g., directly using measurements or indirectly using a lookup table) determine a gain value based on an SRS requirement, a loss of lock avoidance requirement, an OMA value, or a BER value. For example, the controller 150 may select a gain value that results in the electronic device 100 having an SRS value that satisfies an SRS threshold or is within a configured SRS range. Similarly, the controller 150 may select a gain value that is associated with avoiding (or is associated with a threshold likelihood of avoiding) occurrence of a loss of lock scenario. Similarly, as described above, the controller 150 may select a gain value that is associated with achieving a configured OMA value or BER value.

As indicated above, FIG. 1 is provided as an example. Other examples may differ from what is described with regard to FIG. 1.

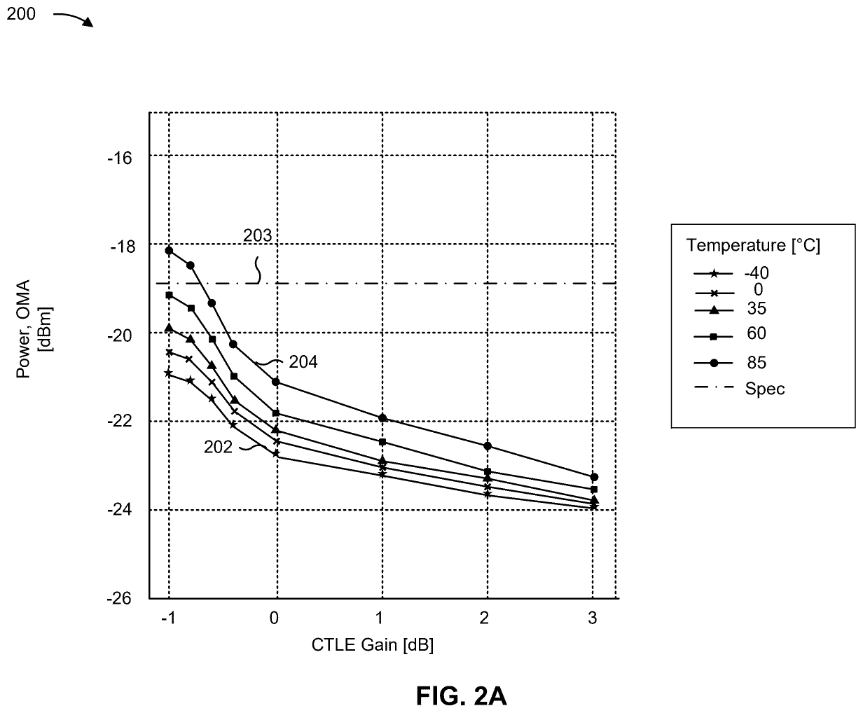

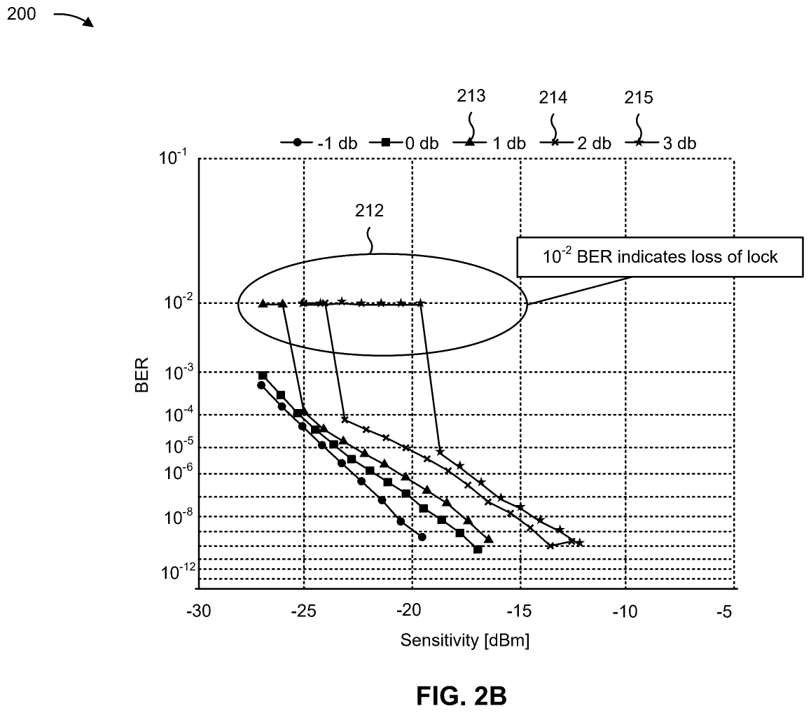

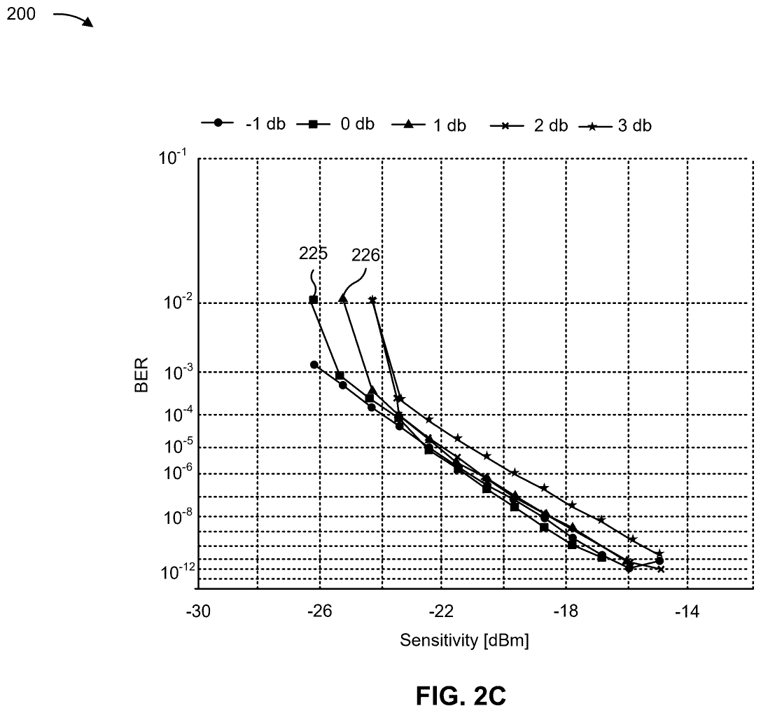

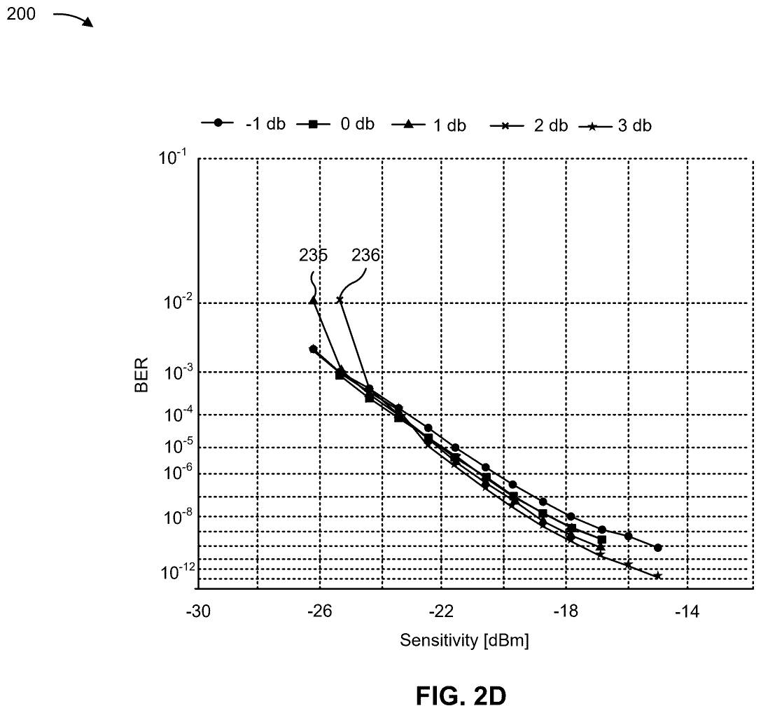

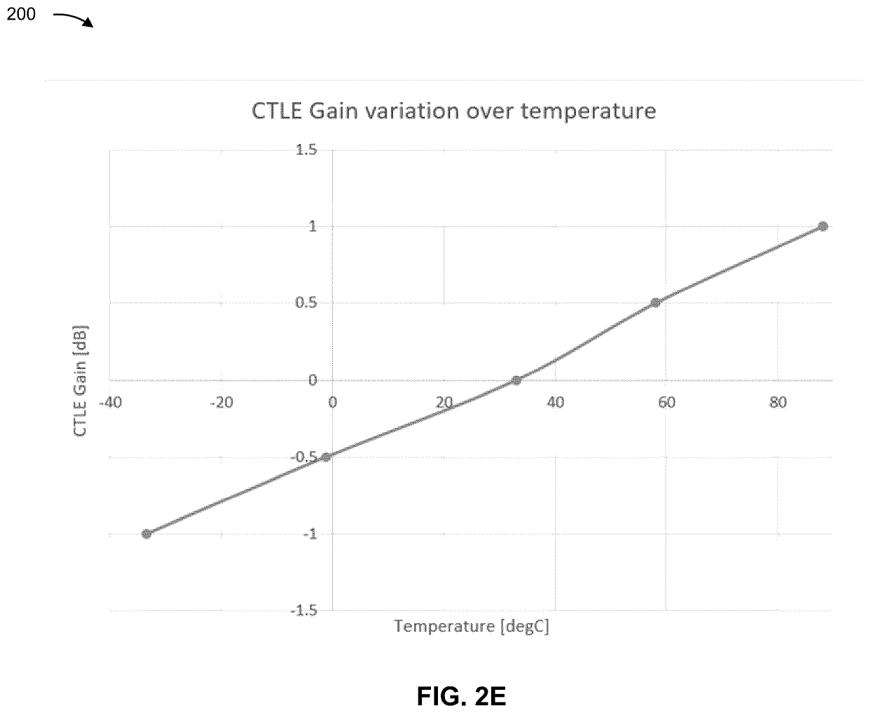

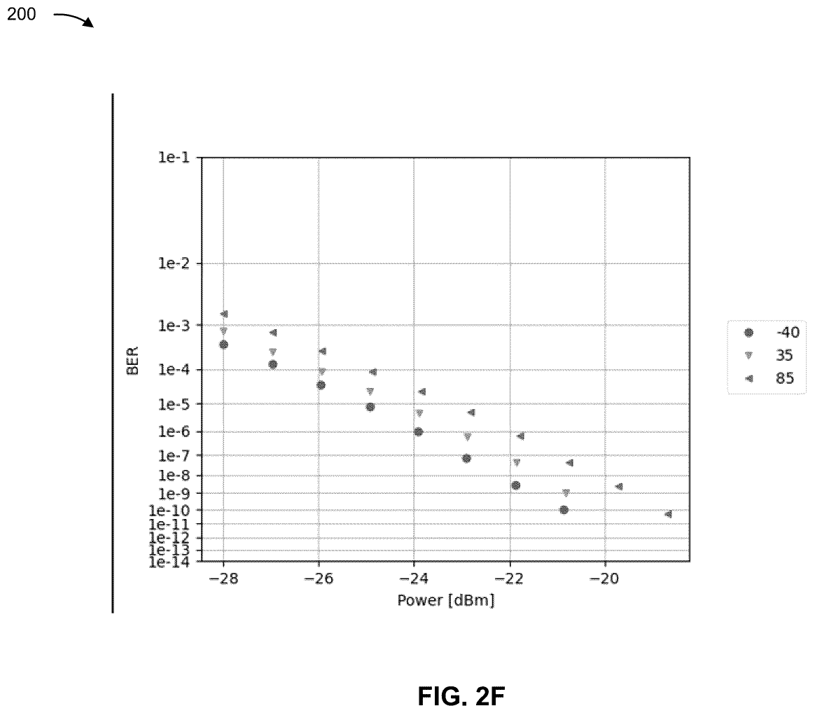

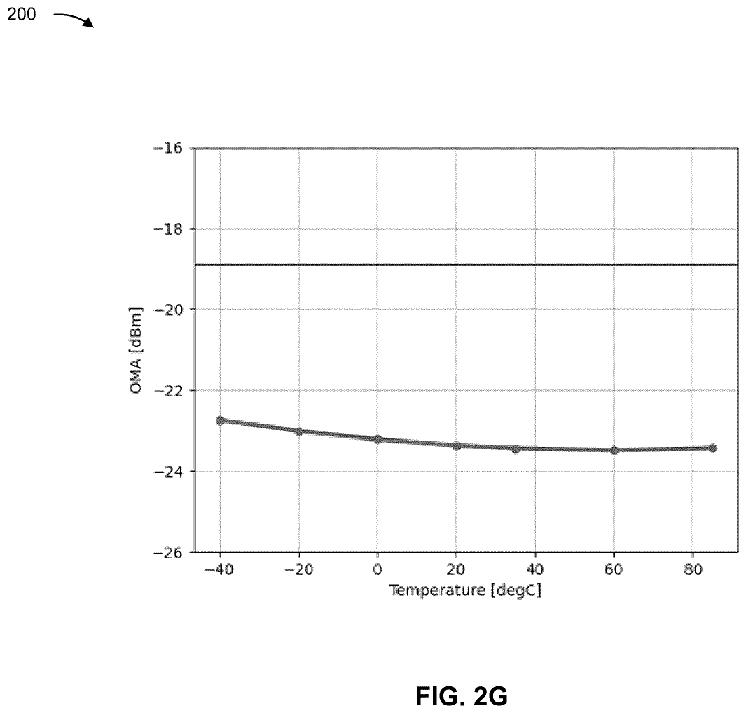

FIGS. 2A-2G are diagrams of an example 200 associated with dynamic gain control for clock and data recovery components. As shown in FIG. 2A, a CTLE gain may be associated with different OMA power values (e.g., in decibel-milliwatts (dBm)) at different temperatures (e.g., in degrees Celsius (C)) under stress receiver sensitivity conditions. For example, at a temperature of −40° C., as shown by reference number 202, CTLE gain values from −1 dB to 3 dB may satisfy a specification, specified for an electronic device, as shown by reference number 203. In contrast, at 85 degrees, as shown by reference number 204, a −1 dB gain may not satisfy the specification shown by reference number 203. Similarly, when a margin of safety is configured for the specification such that an electronic device is to satisfy the specification by at least −2 dB, the electronic device does not satisfy the specification, with the margin of safety, at any temperature in a range from −40° C. to 85° C. with a −1 dB gain.

FIG. 2B shows an example waterfall diagram for a sensitivity relative to a BER value at different CTLE gain values and at a temperature of −40° C. As shown by reference number 212, BER values of approximately 10⁻² indicate a loss of lock scenario. Here, CTLE gains of −1 dB through 0 dB do not result in loss of lock scenarios across different sensitivity values. However, as shown by reference numbers 213, 214, and 215, CTLE gains of 1 dB, 2 dB, and 3 dB, respectively, exhibit loss of lock at lower sensitivity values (e.g., an electronic device with a CTLE gain of 1 dB exhibits a loss of lock at less than −25 dBm sensitivity and an electronic device with a CTLE gain of 3 dB exhibits a loss of lock at less than −19 dBm sensitivity). FIG. 2C shows another example waterfall diagram for a sensitivity relative to a BER value at different CTLE gain values and at a temperature of 35° C. Here, a CTLE gain of up to −0.5 dB, shown by reference number 225, to 3 dB, shown by reference number 226, may result in a loss of lock scenario for lower sensitivity values. As shown, with lower gain values, such as gain values of less than 0 dB (e.g., −1 dB), there is not loss of lock. FIG. 2D shows another example waterfall diagram for a sensitivity relative to a BER value at different CTLE gain values and at a temperature of 85° C. Here, a CTLE gain of 1 dB, shown by reference number 235, to 3 dB, shown by reference number 236, may result in a loss of lock scenario for lower sensitivity values. Further, for lower gain values, such as gain values below 1 dB (e.g., 0 dB or −1 dB), there is not loss of lock.

Accordingly, based on OMA values, under stressed receiver sensitivity conditions, and BER values at different temperatures and CTLE gains, an optimization procedure may result in generation of a mapping of temperatures to CTLE gain values to meet a stressed receiver sensitivity OMA specification and to avoid loss of lock. For example, as shown in FIG. 2E, a plot of temperature values, within an operating range of temperatures, relative to CTLE gain values (e.g., between −1.5 dB and 1.5 dB) is provided. Furthermore, as shown in FIG. 2F, a plot of power relative to BER values is illustrated for a range of temperature conditions (e.g., −40° C., 35° C., and 85° C.). As shown, loss of lock does not occur across the range of temperature conditions when temperature-dependent CTLE gain values are used. As shown in FIG. 2G, a plot of OMA, under stressed receiver sensitivity conditions, relative to temperature is illustrated. Here, a specification may have a threshold of, for example, −19 dBm for the OMA value. As shown, an observed OMA value remains in a range of between −22 dBm and −24 dBm across a temperature range of at least −40° C. to 85° C. (as well as any sub-range thereof), thus passing the specification.

As described above, in some implementations, such a mapping of temperature values to CTLE gain values may be implemented, at the controller 150 of the electronic device 100, using a lookup table of discrete temperature values to discrete CTLE gain values. Additionally, or alternatively, an algorithmic representation (e.g., based on a linear regression to generate a best-fit equation) of the mapping of temperature values to CTLE gain values may be provided to the controller 150, which may use a received temperature value to determine, using the best-fit equation, a corresponding CTLE gain. Although lookup tables and algorithmic representations of a mapping are described herein, other representations may be used, such as other data structures, feedback loops, or determinations. Additionally, although some aspects are described herein in terms of a mapping of temperatures to CTLE gain values, other factors may be used to determine a CTLE gain value and/or a temperature may map to another type of parameter, such as a control signal that causes a CTLE gain value to be provided.

As indicated above, FIGS. 2A-2G are provided as an example. Other examples may differ from what is described with regard to FIGS. 2A-2G.

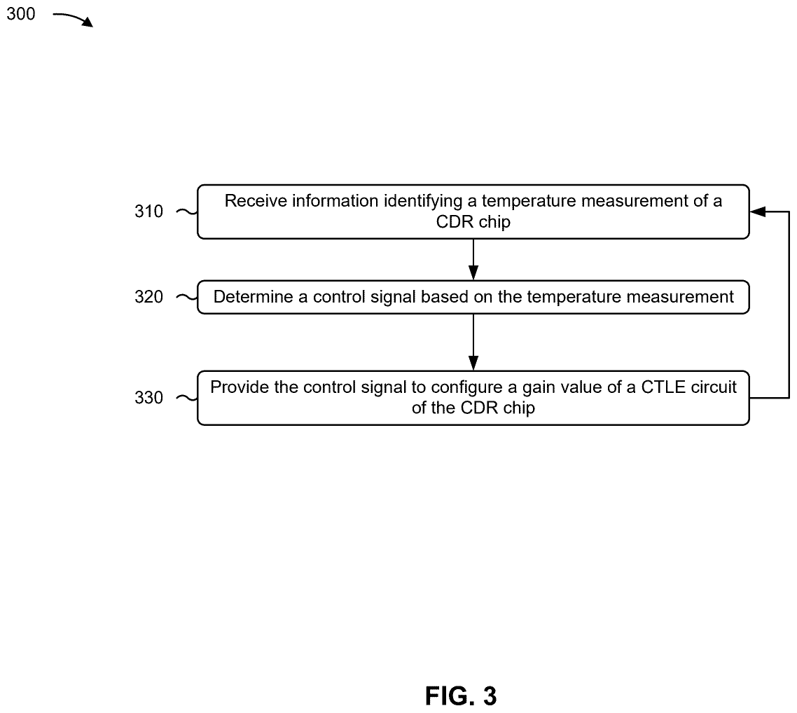

FIG. 3 is a flowchart of an example process 300 associated with dynamic gain control for CDR components. In some implementations, one or more process blocks of FIG. 3 are performed by a controller (e.g., controller 150). In some implementations, one or more process blocks of FIG. 3 are performed by another device or a group of devices separate from or including the controller, such as a temperature measurement component (e.g., the temperature measurement component 140), a CTLE circuit (e.g., the CTLE circuit 130), and/or a CDR chip (e.g., the CDR chip 110). In some implementations, the controller may include one or more components, such as one or more processor components, one or more memory components, one or more register components, an interpolation component, an extrapolation component, or another type of component that may store information or perform a determination.

As shown in FIG. 3, process 300 may include receiving information identifying a temperature measurement of a CDR chip (block 310). For example, the controller may receive information identifying a temperature measurement of a CDR chip, as described above. In some implementations, the controller may receive the information identifying the temperature measurement on a periodic basis. For example, the temperature measurement component may be configured to provide temperature measurements with a configured periodicity. Additionally, or alternatively, the temperature measurement component may provide temperature measurements as a response to a triggering event, such as a temperature deviation (e.g., from a last reported temperature) of more than a threshold amount. In some implementations, the controller may receive the information identifying the temperature measurement based on a request. For example, the controller may request temperature information (e.g., periodically or as a response to an event, such as a loss of lock scenario or an OMA level at a specific BER value being within a threshold amount of a configured specification or margin of safety associated therewith.

As further shown in FIG. 3, process 300 may include determining a control signal based on the temperature measurement (block 320). For example, the controller may determine a control signal based on the temperature measurement, as described above. In some implementations, the controller may determine the control signal based on a mapping of temperature measurements (or outputs of the temperature measurement component) to gain values (or associated control signals). For example, the controller may receive information identifying a temperature measurement and lookup a corresponding control signal for a corresponding gain value. Additionally, or alternatively, the controller may perform an interpolation, extrapolation, or algorithmic determination process to determine a CTLE gain value and associated control signal. For example, the controller may select, using interpolation, a gain value from a set of possible gain values with which the CTLE circuit can be configured, and may generate a control signal to cause the selected gain value to be implemented.

In some implementations, the controller may receive a lookup table from a configuration device. For example, before deployment in an electronic device (e.g., an optical transceiver), the controller may receive information identifying the lookup table from the configuration device. In this case, the controller may store information identifying the lookup table in a register, in firmware, in one or more memories, via a software, firmware, or hardware configuration, or via another data storage component or technique. The configuration device may receive measurements and perform an optimization to generate the lookup table. For example, the configuration device may optimize CTLE gain, for each temperature, against SRS requirements, loss of lock avoidance requirements, OMA values, or BER values, among other examples. Additionally, or alternatively, the controller may generate the lookup table using one or more measurements. For example, the controller may receive a measurement, set a CTLE gain value, determine whether the CTLE gain value results in a specification being satisfied without a loss of lock scenario, and may configure a mapping of the CTLE gain value to a temperature based on the determination.

As further shown in FIG. 3, process 300 may include providing the control signal to configure a gain value of a CTLE circuit of the CDR chip (block 330). For example, the controller may provide the control signal to configure a gain value of a CTLE circuit of the CDR chip, as described above. In some implementations, the CTLE circuit may set a CTLE gain value (or receive a gain of a configured CTLE gain value from another component) based on receiving the control signal. For example, the controller may provide the control signal to the CTLE circuit or to a gain component associated therewith. In some implementations, based on providing the control signal, the controller may receive results of a feedback loop. For example, based on providing the control signal, the temperature measurement component may perform a new temperature measurement and provide the new temperature measurement to the controller. In this case, the controller may provide a new control signal to control the CTLE gain based on the new temperature measurement.

Process 300 may include additional implementations, such as any single implementation or any combination of implementations described below and/or in connection with one or more other processes described elsewhere herein.

In a first implementation, determining the control signal comprises performing a linear interpolation procedure to identify the gain value, between two possible gain values for the CTLE circuit.

In a second implementation, determining the control signal comprises performing an extrapolation procedure to identify the gain value outside a range of configured gain of values for the CTLE circuit.

In a third implementation, the controller is configured with a mapping of temperature measurements to control signals.

In a fourth implementation, determining the control signal comprises determining the control signal based on the mapping of temperature measurements to control signals.

In a fifth implementation, the mapping of temperature measurements to control signals is based on at least one of a stress receiver sensitivity (SRS) requirement, a loss of lock (LOL) avoidance requirement, an optical modulation amplitude, or a bit error rate.

In a sixth implementation, process 300 includes receiving information identifying an updated temperature measurement, the updated temperature measurement identifying a different temperature than the temperature measurement, determining an updated control signal, and providing the updated control signal to configure an updated gain value for the CTLE circuit, the updated gain value being different than the gain value.

Although FIG. 3 shows example blocks of process 300, in some implementations, process 300 includes additional blocks, fewer blocks, different blocks, or differently arranged blocks than those depicted in FIG. 3. Additionally, or alternatively, two or more of the blocks of process 300 may be performed in parallel.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, the term “component” is intended to be broadly construed as hardware, firmware, and/or a combination of hardware and software. It will be apparent that systems and/or methods described herein may be implemented in different forms of hardware, firmware, or a combination of hardware and software. The actual specialized control hardware or software code used to implement these systems and/or methods is not limiting of the implementations. Thus, the operation and behavior of the systems and/or methods are described herein without reference to specific software code—it being understood that software and hardware can be designed to implement the systems and/or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a controller or one or more controller) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

What is claimed is:

1. A clock and data recovery (CDR) chip, comprising:
a continuous time linear equalizer (CTLE) circuit; and
a temperature measurement component,
wherein the CTLE circuit is configurable with a variable gain value,
wherein the variable gain value is based on an output of the temperature measurement component.

2. The CDR chip of claim 1, wherein the variable gain value is based on a temperature measurement performed by the temperature measurement component.

3. The CDR chip of claim 1, wherein the variable gain value is based on at least one of:
a stress receiver sensitivity (SRS) requirement,
a loss of lock (LOL) avoidance requirement,
an optical modulation amplitude, or
a bit error rate.

4. The CDR chip of claim 1, wherein an optical modulation amplitude power satisfies a threshold value for a configured range of gain values for the variable gain value and for a configured temperature range.

5. The CDR chip of claim 4, wherein the configured temperature range is from at least −40 degrees Celsius to at least 85 degrees Celsius, and wherein the configured range of gain values for the variable gain value is at least from −1 decibels to at least 3 decibels.

6. The CDR chip of claim 1, wherein the variable gain value is based on an output of a feedback loop.

7. The CDR chip of claim 1, wherein the variable gain value is based on a mapping of possible outputs of the temperature measurement component to possible variable gain values.

8. The CDR chip of claim 1, further comprising:
an interpolation component configured to set the variable gain value based on an interpolation within a set of possible variable gain values.

9. A method, comprising:
receiving, by a controller, information identifying a temperature measurement of a clock and data recovery (CDR) chip;
determining, by the controller, a control signal based on the temperature measurement; and
providing, by the controller, the control signal to configure a gain value of a continuous time linear equalizer (CTLE) circuit of the CDR chip.

10. The method of claim 9, wherein determining the control signal comprises:
performing a linear interpolation procedure to identify the gain value, between two possible gain values for the CTLE circuit.

11. The method of claim 9, wherein determining the control signal comprises:
performing an extrapolation procedure to identify the gain value outside a range of configured gain values for the CTLE circuit.

12. The method of claim 9, wherein the controller is configured with a mapping of temperature measurements to control signals.

13. The method of claim 12, wherein determining the control signal comprises:
determining the control signal based on the mapping of temperature measurements to control signals.

14. The method of claim 12, wherein the mapping of temperature measurements to control signals is based on at least one of:
a stress receiver sensitivity (SRS) requirement,
a loss of lock (LOL) avoidance requirement,
an optical modulation amplitude, or
a bit error rate.

15. The method of claim 9, further comprising:
receiving information identifying an updated temperature measurement, the updated temperature measurement identifying a different temperature than the temperature measurement;
determining an updated control signal; and
providing the updated control signal to configure an updated gain value for the CTLE circuit, the updated gain value being different than the gain value.

16. An optical transceiver, comprising:
a temperature measurement component; and
a clock and data recovery (CDR) chip,
the CDR chip including:
a continuous time linear equalizer (CTLE) circuit,
wherein the CTLE circuit is set with a variable gain value,
wherein the variable gain value is set based on a temperature measurement performed by the temperature measurement component.

17. The optical transceiver of claim 16, further comprising:
a transmitter,
wherein the transmitter is coupled to a first physical interface and a second physical interface,
wherein the first physical interface is an input to the transmitter and the second physical interface is an output from the transmitter; and
a receiver,
wherein the receiver is coupled to a third physical interface and a fourth physical interface,
wherein the third physical interface is an input to the receiver and the fourth physical interface is an output from the receiver, and
wherein the CDR chip couples the first physical interface to the transmitter and couples the receiver to the fourth physical interface.

18. The optical transceiver of claim 16, further comprising:
a CDR transmit module;
a transmitter driver; and
a CDR receive module.

19. The optical transceiver of claim 16, wherein the variable gain value is based on at least one of:
a stress receiver sensitivity (SRS) requirement,
a loss of lock (LOL) avoidance requirement,
an optical modulation amplitude, or
a bit error rate.

20. The optical transceiver of claim 16, wherein the variable gain value is selected from a discrete quantity of gain settings stored in a register of the CDR chip.
